(19) United States
(12) Patent Application Publication
(10) Pub. No.: US 2012/0049942 A1
(43) Pub. Date: Mar. 1, 2012

(54) SEMICONDUCTOR DEVICE AND CONTACTLESS COMMUNICATION MEDIUM

(75) Inventor: Shuzo Mori, Kawasaki-shi (JP)

(73) Assignee: KABUSHIKI KAISHA TOSHIBA, Tokyo (JP)

(21) Appl. No.: 13/069,567

(22) Filed: Mar. 23, 2011

(30) Foreign Application Priority Data
Aug. 31, 2010 (JP) 2010-193771

(51) Int. Cl. G05F 1/10; G11C 5/14

(52) U.S. Cl. 327/540; 327/530; 327/538

(57) ABSTRACT

According to an embodiment, a semiconductor device includes a functional circuit, an electric current measurement circuit and a control circuit. The functional circuit operates with a supplied electric power. The electric current measurement circuit is configured to measure an electric current based on the electric power. The control circuit is configured to control an operation of the functional circuit in accordance with operation information about the functional circuit and the measured electric current.

### CROSS REFERENCE TO RELATED APPLICATION

This application is based upon and claims the benefit of priority from the prior Japanese Patent Application No. 2010-193771 filed on Aug. 31, 2010 in Japan, the entire contents of which are incorporated herein by reference.

### FIELD

Embodiments described herein relate generally to a semiconductor device and a contactless communication medium.

### BACKGROUND

A contactless communication medium called a wireless IC card (contactless IC card) has been known. The wireless IC card operates using electric power supplied from a radio wave. For example, this kind of wireless IC card is used in a commuter pass (an e-pass) and the like.

In a conventional wireless IC card, a regulator generates a power supply voltage based on the supplied electric power, and the voltage is measured, so that a circuit operation is controlled according to the measured voltage. Even when the supplied electric power is at a level insufficient for the circuit operation (i.e., the electric current is too low), the power supply voltage is raised to a voltage sufficient for the circuit operation based on the characteristics of the regulator. On the other hand, the variation of the generated power supply voltage is usually low when the supplied electric power is at a certain level or more. Accordingly, the supplied electric power cannot be accurately determined based on the measured voltage. Therefore, when the circuit operation is controlled only by determining the voltage, the electric power consumption of the wireless IC card itself may become more than the supplied electric power depending on the supplied electric power, and it may be impossible to normally perform the circuit operation.

Since the wireless IC card operates using the electric power supplied from the radio wave, the supplied electric power may be in sufficient due to a change of an environment that may occur even during a normal operation, and the wireless IC card may fail to normally perform the operation.

For the reasons stated above, there is only a small range of supplied electric power that can ensure the operation of the wireless IC card. Therefore, this imposes a strict limitation on the distance between the wireless IC card and the electric power supply source within which the wireless IC card can operate.

### BRIEF DESCRIPTION OF THE DRAWINGS

FIG. 1 is a conceptual diagram illustrating a principle of operation of a wireless IC card according to a first embodiment of the present invention.

FIG. 2 is a block diagram illustrating the wireless IC card according to the first embodiment of the present invention.

FIG. 3 is a figure illustrating characteristics of an electric current provided to a shunt regulator and a voltage output from the shunt regulator according to the first embodiment.

FIG. 4 is a block diagram illustrating a wireless IC card according to a comparative example.

FIG. 5 is a figure illustrating characteristics of an electric current provided to a shunt regulator and a voltage output from the shunt regulator, according to the comparative example.

FIG. 6 is a conceptual diagram illustrating a relationship between an electric power consumption and an electric power provided in the wireless IC card according to the comparative example.

### DETAILED DESCRIPTION

According to an embodiment, a semiconductor device includes a functional circuit, an electric current measurement circuit and a control circuit. The functional circuit operates with a supplied electric power. The electric current measurement circuit is configured to measure an electric current based on the electric power. The control circuit is configured to control an operation of the functional circuit in accordance with operation information about the functional circuit and the measured electric current.

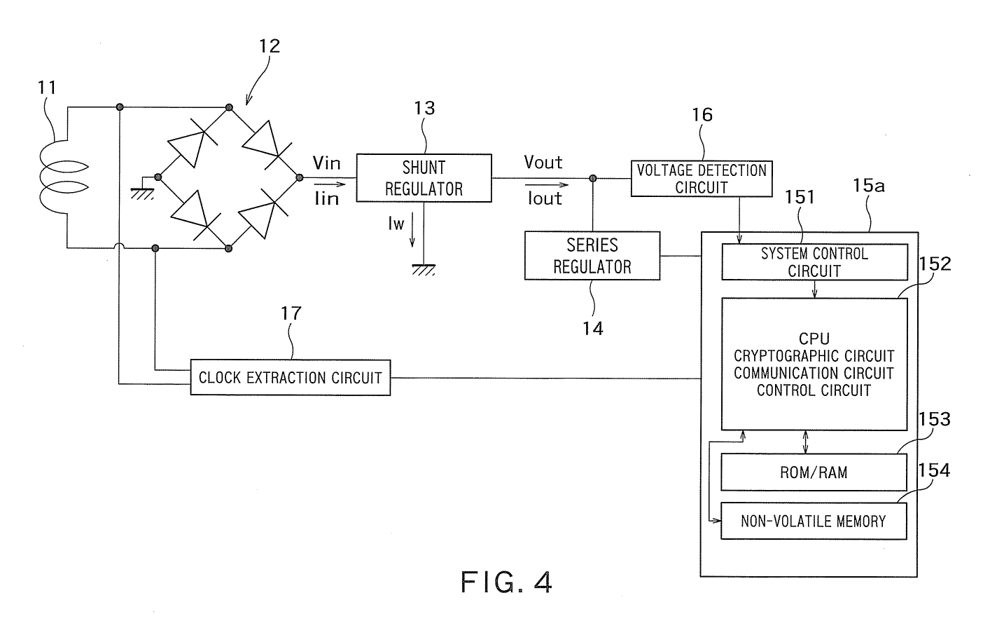

Before describing embodiments of the present invention, a wireless IC card according to a comparative example which is known to the inventor will be described with reference to FIGS. 4 to 6.

FIG. 4 is a block diagram illustrating the wireless IC card according to the comparative example.

As illustrated in FIG. 4, the wireless IC card is generally configured as follows. Electric power is supplied from a radio wave received by an antenna 11. The received electric power is rectified by a rectification circuit 12. A shunt regulator 13 outputs a target power supply voltage Vout and a power supply electric current Iout on the basis of the rectified electric power. The power supply voltage Vout and the power supply electric current Iout are supplied to a functional circuit 15a and the like via a series regulator 14. The radio wave is provided from an external apparatus (not illustrated) serving as an electric power supply source.

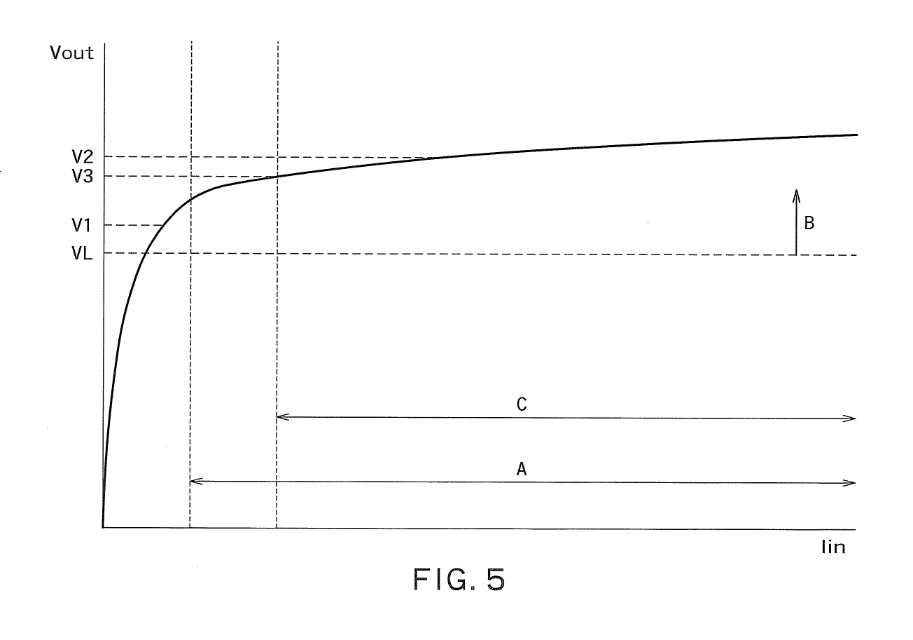

The wireless IC card determines the state of supply of the electric power. When the supply of the electric power is determined to be sufficient, the functional circuit 15a is activated. Whether the supplied electric power is sufficiently provided or not may be determined based on whether the power supply voltage Vout reaches a sufficient voltage range of FIG. 5 (whether the power supply voltage Vout is equal to or more than an environment determination detection voltage (for example, voltage V3)). Accordingly, a voltage detection circuit 16 determines the state of the electric power on the basis of the magnitude of the power supply voltage Vout. When the voltage detection circuit 16 determines that the power supply voltage Vout is equal to or more than the environment determination detection voltage, a system control circuit 151 performs reset release of a processing circuit (CPU and the like) 152 and the like of the functional circuit 15a. Thereby, the functional circuit 15a starts an operation and starts consuming the electric power.

FIG. 5 is a figure illustrating characteristics of an electric current provided to the shunt regulator and a voltage output from the shunt regulator. In FIG. 5, the horizontal axis represents an electric current Iin provided to the shunt regulator 13 on the basis of the supplied electric power, and the vertical axis represents a power supply voltage Vout output from the shunt regulator 13. The electric current Iin is the maximum value that can be output as the power supply electric current Iout.

A range A represents a range in which the power supply voltage Vout is at a certain level or more, and the variation of the power supply voltage Vout is small. The reason why the variation is small is that the shunt regulator 13 controls the power supply voltage Vout so as to maintain a constant value. A range B represents a supply voltage range equal to or more than a circuit operation limit voltage VL in which the circuit can operate. A range C represents a supply current range which is sufficient for allowing the circuit to operate.

In the wireless IC card according to the comparative example, the environmental determination detection voltage may be set in three ways as described below.

(Setting 1) When the environment determination detection voltage is set at a voltage V1 which is close to the circuit operation limit voltage VL, the supplied electric power becomes insufficient due to the electric power consumption in the operation of the wireless IC card itself, and this makes the wireless IC card inoperable.

In other words, this setting allows the functional circuit 15a to be activated even when the wireless IC card is at a location away from the electric power supply source where the wireless IC card receives only a low level of electric power. In many cases, however, the electric power consumption of the wireless IC card is more than the supplied electric power, and the wireless IC card may fail to normally perform the circuit operation.

(Setting 2) When the environment determination detection voltage is set with a margin with respect to the circuit operation limit voltage VL, the determination is made in a range in which the variation of the voltage is small. Accordingly, it is difficult to determine that the wireless IC card can perform an operation unless much electric power is supplied (voltage V2).

In other words, in this setting, the functional circuit 15a cannot be activated unless the wireless IC card is at a location close to the electric power supply source where the wireless IC card can receive a high level of electric power.

(Setting 3) When the environment determination detection voltage is set at the voltage V3 between the voltage V1 and the voltage V2, the wireless IC card can operate with a low level electric power which is less than the above (setting 2). It is difficult to determine the supplied electric power only from the voltage since the voltage is in the range in which the variation of the voltage is small.

In other words, in this setting, even when the distance between the wireless IC card and the electric power supply source is farther than the above (setting 2), the wireless IC card can be activated and normally perform the operation. However, a high level of measuring accuracy is required to make the determination on the basis of the voltage.

As described above, the wireless IC card according to the comparative example cannot accurately determine the supplied electric power only from the voltage. Therefore, the environmental determination detection voltage needs to be set at a voltage higher than the minimum voltage at which the wireless IC card can operate in fact, and it is difficult for the wireless IC card to operate in the entire range A.

In this case, the electric power consumption for allowing the functional circuit 15a to operate is different according to processing. For example, when the functional circuit 15a operates in a high speed cryptographic calculation processing mode, the wireless IC card consumes much electric power. On the other hand, when the functional circuit 15a does not execute any calculation (for example, data transfer is performed within the wireless IC card), the wireless IC card does not consume much electric power.

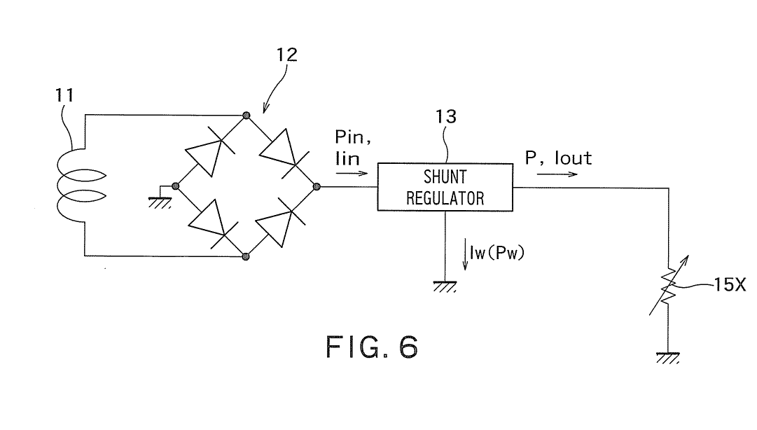

The electric power that is provided but is not consumed by the functional circuit 15a is consumed as heat in the shunt regulator 13. This will be described with reference to FIG. 6.

FIG. 6 is a conceptual diagram illustrating a relationship between an electric power consumption and an electric power provided in the wireless IC card according to the comparative example.

As illustrated in FIG. 6, an electric power Pin provided to the shunt regulator 13 can be divided into an electric power (electric power consumption P) consumed by the operation of the functional circuit 15a (load 15X) and an unnecessary electric power (redundant electric power consumption Pw) that is not consumed by the operation of the functional circuit 15a (load 15X). The unnecessary electric power is discarded (consumed) in the shunt regulator 13. In terms of electric current, a total electric current Iin flowing from the rectifier 12 to the shunt regulator 13 can be divided into an electric current Iout flowing through the functional circuit 15a and an electric current Iw discarded in the shunt regulator 13.

The inventor of the present application has uniquely found that the following two states may be considered when the electric current discarded in the shunt regulator 13 is low.

State 1: The supplied electric power Pin is sufficient, but the electric power is consumed to allow the functional circuit 15a to operate. Accordingly, only a small amount of electric power is discarded by the shunt regulator 13.

State 2: The supplied electric power Pin is low.

In embodiments of the present invention as described below, an electric power consumption P consumed by the functional circuit 15a of the wireless IC card is reduced in the above state 2, whereby the wireless IC card can operate using the supplied electric power Pin or less. However, it is necessary to distinguish the state 1 and the state 2. Therefore, it is necessary for the wireless IC card to be able to determine the degree of the supplied electric power Pin as a plurality of levels, and it is necessary for the functional circuit 15a to have a plurality of operation modes.

The inventor has made the present invention on the basis of the above unique findings.

The embodiments of the present invention will be hereinafter described with reference to drawings. These embodiments are not intended to limit the present invention.

### First Embodiment

One of features of the present embodiment is that an operation mode of a functional circuit is changed according to an electric current discarded in a shunt regulator and the operation mode of the functional circuit.

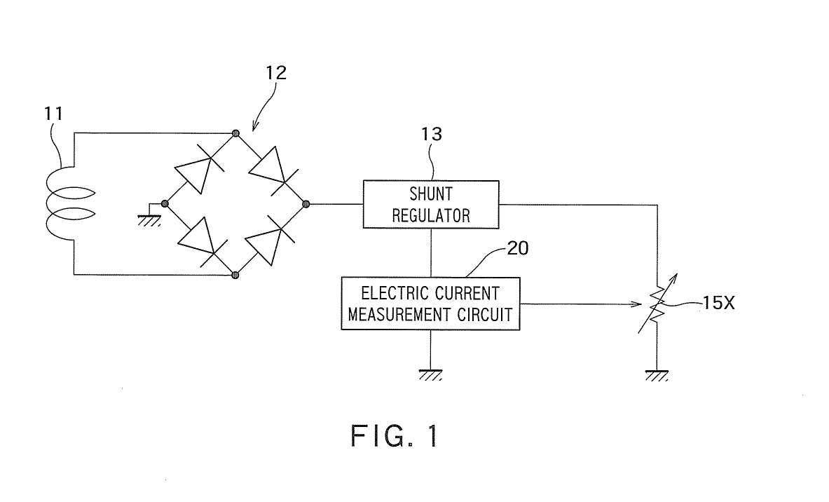

FIG. 1 is a conceptual diagram illustrating a principle of operation of a wireless IC card according to the first embodiment of the present invention.

The wireless IC card further includes an electric current measurement circuit 20 for measuring a discarded electric current Iw in addition to the comparative example of FIG. 4. Then, the wireless IC card changes an operation mode (consumed electric power) of a functional circuit serving as a load 15X in accordance with an electric current measured by the electric current measurement circuit 20. In other words, as illustrated in FIG. 1, the wireless IC card operates so as to change the impedance of the load 15X in accordance with the measured electric current. This will be described below in detail.

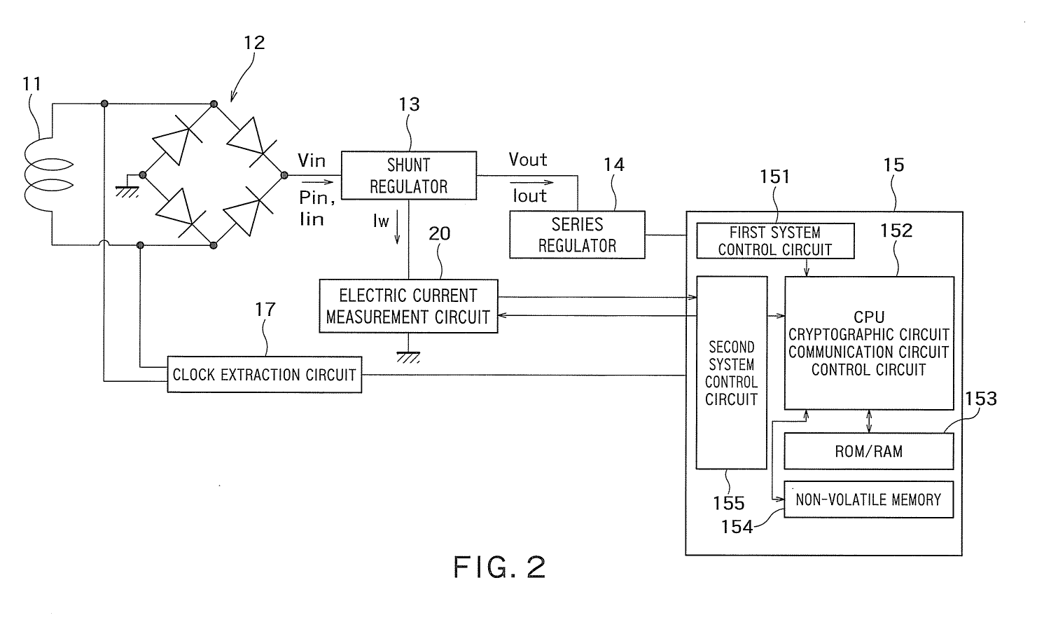

FIG. 2 is a block diagram illustrating a wireless IC card according to the first embodiment of the present invention.

As illustrated in FIG. 2, the wireless IC card includes an antenna (electric power generation circuit) 11, a rectification circuit (electric power generation circuit) 12, a shunt regulator 13, a series regulator 14, a functional circuit 15, a clock extraction circuit 17, and the electric current measurement circuit 20. The functional circuit 15 includes a first system control circuit 151, a processing circuit 152, a ROM/RAM 153, a non-volatile memory 154, and a second system control circuit (control circuit) 155. The processing circuit 152 includes a CPU, a cryptographic circuit, a communication circuit, a control circuit, and the like.

In other words, the wireless IC card includes the electric current measurement circuit 20 and the second system control circuit 155 in addition to the elements of the comparative example of FIG. 5. But the wireless IC card does not have the voltage detection circuit 16 according to the comparative example.

The wireless IC card (for example, a commuter pass) operates using an electric power obtained from a radio wave supplied from an external apparatus (for example, automatic ticket gate), not illustrated.

The antenna 11 receives a radio wave from the external apparatus. The rectification circuit 12 rectifies the electric power provided by the received radio wave. In this case, a bridge diode in which four diodes are connected is used as an example of the rectification circuit 12.

The shunt regulator 13 provides both a power supply voltage Vout, which is controlled to be predetermined values, and a power supply electric current Iout to the functional circuit 15 via the series regulator 14 on the basis of the electric power Pin (voltage Vin, electric current Iin) provided from the rectification circuit 12. The series regulator 14 stabilizes and outputs the received power supply voltage Vout and outputs the received power supply electric current Tout as it is.

The shunt regulator 13 discards a part of the electric current Iin that is not provided to the functional circuit 15. The discarded electric current Iw flows via the electric current measurement circuit 20 to a ground point (ground).

The electric current measurement circuit 20 measures the electric current Iw discarded in the shunt regulator 13 (electric current based on the supplied electric power) in order to determine the amount of the supplied electric power Pin. The electric current measurement circuit 20 can give the level of the discarded electric current Iw, as a plurality of states, to the second system control circuit 155.

The reason why the electric power is determined on the basis of the electric current is that, as described above with reference to FIG. 5, usually there is only a small voltage difference within a range in which the wireless IC card can operate, and it is difficult to precisely determine the level of the supplied electric power on the basis of the voltage, although it is possible to roughly determine whether a sufficient electric power is supplied or not on the basis of the voltage.

The clock extraction circuit 17 extracts a clock signal included in the radio wave received by the antenna 11, and provides the clock signal to the functional circuit 15.

The functional circuit 15 operates on the basis of the power supply voltage Vout and the power supply electric current Iout (electric power generated by the antenna 11 and the rectification circuit 12) provided by the shunt regulator 13, and performs processing for transmitting information between the wireless IC card and the external apparatus. The functional circuit 15 performs various kinds of processing in synchronization with, for example, the clock signal provided by the clock extraction circuit 17 or the clock signal generated in the functional circuit 15.

The functional circuit 15 includes a plurality of operation modes (low speed operation mode and high speed operation mode) in which electric power consumptions are different from each other. The electric power consumption is larger in the high speed operation mode than in the low speed operation mode.

The second system control circuit 155 controls the functional circuit 15 so that the functional circuit 15 operates in either the low speed operation mode or the high speed operation mode in accordance with the operation information (low speed/high speed operation mode) of the functional circuit 15 and the electric current measured by the electric current measurement circuit 20. In other words, the second system control circuit 155 determines, from the level of the electric power supply, an operation mode in which the functional circuit 15 can operate, and appropriately sets the operation mode of the functional circuit 15.

For example, the high speed operation mode includes a high speed cryptographic calculation processing mode and an authentication processing mode. For example, the low speed operation mode includes a low speed cryptographic calculation processing mode and a data transfer mode. In the low speed cryptographic calculation processing mode, processing is performed with a clock signal having a frequency lower than the frequency used in the high speed cryptographic calculation processing mode. In the data transfer mode, data transfer within the functional circuit 15 (for example, data transfer between the ROM/RAM 153 and the non-volatile memory 154) is performed.

The second system control circuit 155 switches the operation mode to the high speed operation mode when the functional circuit 15 is operating in the low speed operation mode and the electric current measured by the electric current measurement circuit 20 is equal to or more than a first value.

The second system control circuit 155 switches the operation mode to the low speed operation mode when the functional circuit 15 is operating in the high speed operation mode and the electric current measured by the electric current measurement circuit 20 is less than a second value. The first value is larger than the second value.

In the present embodiment, the second system control circuit 155 sets the detection level (the above first value or the second value) of the electric current measurement circuit 20 in accordance with the operation mode. The electric current measurement circuit 20 outputs, to the second system control circuit 155, whether the discarded electric current Iw is equal to or more than a configured detection level.

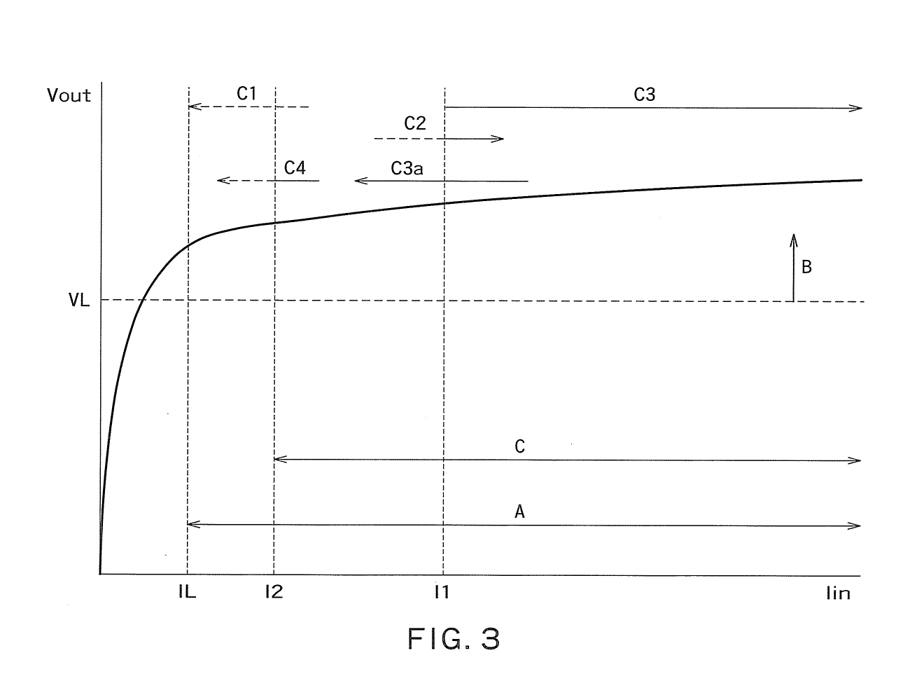

Subsequently, an operation of the wireless IC card will be described in detail with reference to FIG. 3.

FIG. 3 is a figure illustrating characteristics of an electric current provided to the shunt regulator and a voltage output from the shunt regulator according to the present embodiment. The horizontal axis of FIG. 3 represents the electric current Iin provided to the shunt regulator 13 on the basis of the supplied electric power. The vertical axis of FIG. 3 represents a power supply voltage Vout output from the shunt regulator 13. The electric current Iin is the maximum value that can be output as the power supply electric current Iout. The current-voltage characteristic is the same as the current-voltage characteristic in FIG. 5 according to the comparative example.

First, when the wireless IC card comes in proximity to the external apparatus, the antenna 11 of the wireless IC card receives a weak radio wave from the external apparatus. The rectification circuit 12 rectifies the electric power provided by the received radio wave. The shunt regulator 13 generates the power supply voltage Vout on the basis of the electric power supplied from the rectification circuit 12. At this occasion, the functional circuit 15 is not operating. Accordingly, the power supply electric current Iout does not flow to the functional circuit 15, and almost all the electric current Iin flows to a ground point via the electric current measurement circuit 20 as the discarded electric current Iw. The electric current measurement circuit 20 measures the discarded electric current Iw. When the wireless IC card further moves closer to the external apparatus, the strength of the received radio wave increases, and the discarded electric current Iw also increases. When the discarded electric current Iw attains a value equal to or more than a predetermined value IwL (in other words, the electric current Iin attains a value equal to or more than the value IL of FIG. 3), the second system control circuit 155 controls the first system control circuit 151 so that the first system control circuit 151 releases reset of the processing circuit 152 and the like of the functional circuit 15. As a result, the power supply electric current Iout flows to the functional circuit 15, and the functional circuit 15 performs activation processing and the like.

The operation mode of the wireless IC card is set according to the supplied electric power. The following four cases are considered as the states of the supplied electric power during operation.

Case 1: Supplied electric power is low (C1 of FIG. 3).

When the supplied electric power is low, and the functional circuit 15 does not consume much electric power, the discarded electric current Iw is low. Therefore, the second system control circuit 155 prohibits the high speed operation mode in which electric power consumption is high, and sets the functional circuit 15 in the low speed operation mode in which electric power consumption is low, whereby calculations and processing are limited to the minimum operations according to the specification. As a result, the wireless IC card can maintain a normal operation state.

As described above, for example, when the functional circuit 15 is activated, the functional circuit 15 is activated in the low speed operation mode after reset release. Therefore, when the discarded electric current Iw is low, the second system control circuit 155 can determine that the state of electric power supply is in the state of the case 1.

In FIG. 3, the functional circuit 15 is set in the low speed operation mode during the periods indicated by broken lines of arrows C1 to C4, and is set in the high speed operation mode during the periods indicated by the solid lines thereof.

Case 2: The state of electric power supply changes from a low electric power state to a sufficient electric power state (C2 of FIG. 3).

The amount of supply of electric power increases in the state where the second system control circuit 155 prohibits the high speed operation mode in which the electric power consumption is high, namely, in the state where not so much electric power is consumed by the operation of the functional circuit 15. Therefore, the discarded electric current Iw increases. When the discarded electric current Iw attains a value equal to or more than a first value Iw1 (i.e., the electric current Iin attains a value equal to or more than a value I1), the second system control circuit 155 permits the high speed operation mode in which the electric power consumption is high, so that the functional circuit 15 can perform calculations consuming much electric power and high speed processing.

Case 3: Sufficient electric power is supplied (C3 of FIG. 3).

Since the second system control circuit 155 permits the high speed operation mode in which the electric power consumption is high, the functional circuit 15 can perform calculations consuming much electric power and high speed processing. At this occasion, the second system control circuit 155 manages information indicating that the functional circuit 15 is operating in the high speed operation mode in which the electric power consumption is high. In view of the above facts, it can be determined that the functional circuit 15 itself is consuming electric power until the discarded electric current Iw decreases to a second value Iw2 of the following case 4 (C3a of FIG. 3).

Case 4: The state of electric power supply changes from a sufficient electric power state to a low electric power state (C4 of FIG. 3).

Since the amount of supply of electric power decreases in the state where the second system control circuit 155 permits the operation mode in which the electric power consumption is high, the discarded electric current Iw decreases, and attains a value less than a second value Iw2 (i.e., the electric current Iin attains a value less than a value I2). Therefore, the second system control circuit 155 prohibits the high speed operation mode in which the electric power consumption is high, and sets the functional circuit 15 in the low speed operation mode, whereby calculations and processing are limited to the minimum operations according to the specification. As a result, the wireless IC card can maintain a normal operation state. In other words, the wireless IC card returns back to the state of the case 1.

However, it may be impossible to maintain a normal operation when a time needed for changing to the low speed operation mode is longer than a time in which the supplied electric power decreases, because the supplied electric power decreases during the operation in the high speed operation mode in which the electric power consumption is high. In such case, the normal operation can be maintained by changing the operation mode while the discarded electric current Iw still remains to some extent.

As described in the case 1 to the case 4 as described above, the second system control circuit 155 switches the operation mode so that the relationship between the operation mode and the electric current Iin has hysteresis.

As described above, according to the present embodiment, the electric current measurement circuit 20 measures the discarded electric current Iw, and the second system control circuit 155 controls the functional circuit 15 so that the functional circuit 15 is set in the high speed operation mode or the low speed operation mode in accordance with the measured current and the operation mode of the functional circuit 15. Therefore, an operation mode appropriate for the supplied electric power Pin can be selected. In other words, even when the supplied electric power Pin decreases, the functional circuit 15 can operate in the low speed operation mode in which the electric power consumption is low. Therefore, the wireless IC card can maintain a normal operation state using the supplied electric power Pin. This allows the wireless IC card to continue processing without rebooting, and expands the operable range of the supplied electric power as compared with the comparative example. Therefore, the wireless IC card can operate in a wider range of distance from the electric power supply source than the comparative example. Moreover, the discarded electric current Iw, which is not used by the comparative example, can be effectively used.

However, the processing speed may get lower because of the low speed operation mode.

Alternatively, a plurality of other values may be set between the first value Iw1 and the second value Iw2, and the operation mode may be switched to one for an intermediate electric power consumption on the basis of these values.

### Second Embodiment

In the first embodiment, the electric current discarded by the shunt regulator is measured. In the present embodiment, however, the entire electric current supplied by a wireless radio wave is measured.

In a wireless IC card according to the present embodiment, the position where an electric current measurement circuit 20 is connected is different from that of the first embodiment. The electric current measurement circuit 20 measures an electric current Iin between a bridge diode 12 and a shunt regulator 13 of FIG. 2. In other words, the electric current measurement circuit 20 measures the electric current Iin provided to a shunt regulator (constant voltage circuit) 13, as an electric current based on an electric power. The configurations other than the above are the same as those of the first embodiment as illustrated in FIG. 2. Accordingly the same constituent elements are denoted with the same reference numerals, and description thereabout will not be repeated.

In the present embodiment, the measured electric current Iin is proportional to a supplied electric power Pin. Accordingly, an operation mode of a functional circuit 15 may be simply controlled on the basis of the measured total electric current Iin. Therefore, the second embodiment is different from the first embodiment in that it is not necessary to consider the relationship between the operation state (operation mode) of the functional circuit 15 and the discarded electric current Iw.

As described in the first embodiment, the second system control circuit 155 switches the operation mode of the functional circuit 15 to the high speed operation mode when the functional circuit 15 is operating in a low speed operation mode and the current measured by the electric current measurement circuit 20 is equal to or more than a first value. In the present embodiment, a value I1 of FIG. 3 is used as the first value.

On the other hand, the second system control circuit 155 switches the operation mode of the functional circuit 15 to the low speed operation mode when the functional circuit 15 is operating in a high speed operation mode and the current measured by the electric current measurement circuit 20 is less than a second value. In the present embodiment, a value I2 of FIG. 3 is used as the second value.

As described above, the present embodiment provides the same effects as those of the first embodiment.

However, the present embodiment is different from the first embodiment in that the discarded electric current Iw, which is not used for the operation of the functional circuit 15 and the like, is not measured. In the first embodiment, the electric power is lost when the electric current is measured, but the lost electric power is to be originally discarded. Therefore, this does not waste any electric power. In the present embodiment, when the electric current Iin is measured, the originally usable electric power is lost.

Each embodiment as described above provides a semiconductor device and a contactless communication medium which can operate with a wide range of supplied electric power.

The embodiments of the present invention have been hereinabove described in detail. However, the specific configuration is not limited to the above embodiments, and the present invention can be modified in various manners and carried out without deviating from the gist of the present invention.

For example, the voltage detection circuit 16 according to the comparative example may be provided, and the voltage detection circuit 16 may perform reset release of the processing circuit 152 and the like of the functional circuit 15.

The functions of the electric current measurement circuit 20 and the second system control circuit 155 are merely examples. The electric current measurement circuit 20 and the second system control circuit 155 may have any function as long as they can determine whether the discarded electric current Iw is equal to or more than the detection level (the above first value or the second value) according to the operation mode. For example, the electric current measurement circuit 20 may output information about the value of the discarded electric current Iw to the second system control circuit 155, and the second system control circuit 155 may determine whether the discarded electric current Iw is equal to or more than the detection level according to the operation mode.

The wireless IC card may not have the series regulator 14.

The external apparatus may be a reader/writer connected to a cash register used in a shop and the like, or may be a personal reader/writer and the like connected to a personal computer.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a functional circuit operating with a supplied electric power;
an electric current measurement circuit configured to measure an electric current based on the electric power; and
a control circuit configured to control an operation of the functional circuit in accordance with operation information about the functional circuit and the measured electric current.

2. The semiconductor device according to claim 1, wherein the functional circuit comprises a plurality of operation modes in which electric power consumptions are different from each other,
and wherein the control circuit uses each of the operation modes as the operation information about the functional circuit, and the control circuit controls the functional circuit so that the functional circuit operates in one of the plurality of operation modes.

3. The semiconductor device according to claim 2,
wherein the plurality of operation modes comprise a low speed operation mode and a high speed operation mode,
wherein an electric power consumption is higher in the high speed operation mode than in the low speed operation mode,
and wherein when the functional circuit is operating in the low speed operation mode and the measured electric current is equal to or more than a first value, the control circuit switches the operation mode to the high speed operation mode,
when the functional circuit is operating in the high speed operation mode and the measured electric current is less than a second value, the control circuit switches the operation mode to the low speed operation mode,
and wherein the first value is more than the second value.

4. The semiconductor device according to claim 3, wherein the high speed operation mode comprises a high speed cryptographic calculation processing mode,
and the low speed operation mode comprises a low speed cryptographic calculation processing mode,
and wherein the functional circuit performs processing in the low speed cryptographic calculation processing mode, using a clock signal having a frequency lower than a frequency used in the high speed cryptographic calculation processing mode.

5. The semiconductor device according to claim 1, further comprising a shunt regulator configured to supply a power supply voltage and a power supply electric current to the functional circuit based on the supplied electric power, and configured to discard an electric current not supplied to the functional circuit,
wherein the electric current measurement circuit measures the electric current discarded in the shunt regulator, as the electric current based on the electric power.

6. The semiconductor device according to claim 5, wherein the electric current discarded in the shunt regulator flows to a ground point via the electric current measurement circuit.

7. The semiconductor device according to claim 5, further comprising a series regulator connected between the shunt regulator and the functional circuit,
wherein the series regulator stabilizes the power supply voltage received from the shunt regulator, and outputs the stabilized power supply voltage to the functional circuit, and wherein the series regulator outputs the power supply electric current received from the shunt regulator to the functional circuit.

8. The semiconductor device according to claim 1, further comprising a constant voltage circuit configured to supply a power supply voltage and a power supply electric current to the functional circuit based on the supplied electric power,
wherein the electric current measurement circuit measures an electric current supplied to the constant voltage circuit, as the electric current based on the electric power.

9. The semiconductor device according to claim 1, wherein the electric power is obtained from a radio wave supplied from an external apparatus.

10. A contactless communication medium operating with an electric power obtained from a radio wave supplied from an external apparatus, the contactless communication medium comprising:
an electric power generation circuit configured to receive the radio wave from the external apparatus and configured to generate an electric power from the radio wave;
a functional circuit operating with the electric power generated by the electric power generation circuit, and performing processing in order to exchange information with the external apparatus;
an electric current measurement circuit configured to measure an electric current based on the electric power; and
a control circuit configured to control an operation of the functional circuit in accordance with operation information about the functional circuit and the measured electric current.

11. The contactless communication medium according to claim 10, wherein the functional circuit comprises a plurality of operation modes in which electric power consumptions are different from each other,
and wherein the control circuit uses each of the operation modes as the operation information about the functional circuit, and the control circuit controls the functional circuit so that the functional circuit operates in one of the plurality of operation modes.

12. The contactless communication medium according to claim 11,
wherein the plurality of operation modes comprise a low speed operation mode and a high speed operation mode,
wherein an electric power consumption is higher in the high speed operation mode than in the low speed operation mode,
and wherein when the functional circuit is operating in the low speed operation mode and the measured electric current is equal to or more than a first value, the control circuit switches the operation mode to the high speed operation mode,
when the functional circuit is operating in the high speed operation mode and the measured electric current is less than a second value, the control circuit switches the operation mode to the low speed operation mode,
and wherein the first value is more than the second value.

13. The contactless communication medium according to claim 12, wherein the high speed operation mode comprises a high speed cryptographic calculation processing mode,
and the low speed operation mode comprises a low speed cryptographic calculation processing mode,
and wherein the functional circuit performs processing in the low speed cryptographic calculation processing mode, using a clock signal having a frequency lower than a frequency used in the high speed cryptographic calculation processing mode.

14. The contactless communication medium according to claim 10, further comprising a shunt regulator configured to supply a power supply voltage and a power supply electric current to the functional circuit based on the supplied electric power, and configured to discard an electric current not supplied to the functional circuit,
wherein the electric current measurement circuit measures the electric current discarded in the shunt regulator, as the electric current based on the electric power.

15. The contactless communication medium according to claim 14, wherein the electric current discarded in the shunt regulator flows to a ground point via the electric current measurement circuit.

16. The contactless communication medium according to claim 14, further comprising a series regulator connected between the shunt regulator and the functional circuit,
wherein the series regulator stabilizes the power supply voltage received from the shunt regulator, and outputs the stabilized power supply voltage to the functional circuit, and wherein the series regulator outputs the power supply electric current received from the shunt regulator to the functional circuit.

17. The contactless communication medium according to claim 10, further comprising a constant voltage circuit configured to supply a power supply voltage and a power supply electric current to the functional circuit based on the supplied electric power, wherein the electric current measurement circuit measures an electric current supplied to the constant voltage circuit, as the electric current based on the electric power.

18. The contactless communication medium according to claim 10, wherein the electric power generation circuit comprises
an antenna configured to receive the radio wave from the external apparatus, and
a rectification circuit configured to rectify the electric power provided from the received radio wave.

19. The contactless communication medium according to claim 18, wherein the rectification circuit is a bridge diode.
